(19) United States
(12) Patent Application Publication
(10) Pub. No.: US 2011/0100430 A1
(43) Pub. Date: May 5, 2011

(54) Hybrid photovoltaic and thermionic energy converter

(75) Inventors: Robert C. Zak, JR., Bolton, MA (US); Jon P. Wade, Reno, NV (US)

(73) Assignee: AgilePower Systems, Inc, Bolton, MA (US)

(21) Appl. No.: 12/590,304

(22) Filed: Nov. 5, 2009

(51) Int. Cl. H01L 31/058

(52) U.S. Cl. 136/248

(57) ABSTRACT

The current invention uses a combination of technologies from dye-sensitized solar cells, and from thermionic generators, to form a unique, efficient, broad spectrum solar radiation to electric power converter. Light passing through the cell first passes through a dye-sensitized matrix of nanoporous semiconductor. Light within the absorption spectrum of the dye is absorbed and converted into electrons which are injected into the conduction band of the semiconductor matrix. Light, which is not absorbed by the dye, passes on to cathode. The cathode is heated upon absorbing the incoming radiation. At a temperature dependent on the work function of the cathode, the cathode emits electrons thermionically, thereby cooling the cathode. These electrons replenish the electrons in the dye, thus completing the flow of current between cathode and anode. The hot cathode is thermally isolated from portions of the device at ambient temperature, thereby minimizing parasitic thermal loss. The device produces electricity similar to a two junction photovoltaic cell in that the anode is added to the cathode voltage.

### BACKGROUND

Modern human civilization relies on the cheap and abundant supply of energy. Since the industrial revolution, this energy has been provided largely by combustion of fossil fuels (coal, oil, natural gas). Since humankind is consuming these fuels (much) faster than they are being produced, eventually, and possibly within the foreseeable future, this source of energy will be neither abundant nor inexpensive. In addition, burning fossil fuels leads to the introduction of large quantities of heat trapping “green house” gases, such as carbon-dioxide, which is strongly implicated in a global increase in planetary mean temperature. Given these shortcomings, numerous attempts have been made to make use of other primary energy sources, especially renewable, and non-polluting sources. These include hydroelectric, wind, wave, geothermal, and solar. Solar is perhaps the most promising, since it has been shown to be the only renewable energy source capable of meeting human-kind's increasing energy needs [smil2003].

Solar converters produce usable electrical, thermal, or chemical energy based on radiation from the sun. Given the extremely high “thermal quality” of solar radiation (approximately 5700K, vs. earth's mean temperature of approximately 300K), the thermodynamically limited conversion efficiency is nearly 70% [badescu2000]. Unfortunately, it has been difficult to achieve, or even approach this limit, especially with cost effective technologies.

The current invention is related to two well-known technologies for solar energy conversion: Dye Sensitized Solar (Photovoltaic) Cells (DSSC) [gratzel2003] and Thermionic converters [houston1965]. Although related, the current invention substantially improves on the efficiency of solar conversion and addresses key shortcomings of the two systems.

For DSSC, these shortcomings include: Requirement for an interstitial liquid or solid electrolyte to replenish photo-generated electrons in the dye; and limited voltage output due to recombination current at the interface of the dye and the porous semiconductor matrix and/or leakage between semiconductor matrix and electrolyte.

For thermionic converters, these shortcomings include: very high cathode temperatures required by high work function material necessary for efficient operation. Very high temperature cathodes reduce overall efficiency since much of the thermal energy is radiated away. Very high temperature operation also greatly reduces the choice of viable materials and complicates the mechanical design of the system.

Both designs are limited to a single energy conversion step: in the case of the DSSC, the conversion step is photovoltaic, and takes place when a photoexcited electron is injected into the conduction band of the nanocrystalline semiconductor matrix; in the case of the thermionic converter, the conversion step takes place when a thermal electron is emitted from the hot cathode. The single conversion step limits the efficiency of both converters.

The hybrid design shares with the DSSC a separation of the photo absorption and charge transport, and an arrangement of a porous nanocrystalline semiconductor matrix with an adsorbed dye monolayer which, upon insolation, injects electrons into the conduction band of the semiconductor matrix. These electrons are then conducted via diffusion to a transparent contact through which the insolation passes. However, rather than being replenished by a chemical reduction/oxidation (redox) cycle of an interstitial electrolyte, the electrons are replenished from a supply of thermionic electrons in a controlled atmosphere between the cathode and anode. The thermionic electrons are supplied, in turn, by solar heating of the cathode.

The present design has the advantage over current DSSC in that it does not require a liquid or solid electrolyte between the dye sensitized semiconductor matrix and the back conductor to resupply electrons to the dye—these electrons are generated thermionically and flow through a controlled atmosphere with low chemical activity and high stability. The resulting arrangement makes efficient use of the solar spectrum—absorbing with high efficiency electrons in the absorption spectrum of the dye, and absorbing the remainder of the solar spectrum on the hot cathode. The operation of the anode as an electron-negative surface enables absorption of thermionic electrons without requiring an ultra-low work function anode surface, thus allowing the cathode to operate with a low-function emitter and relatively low temperatures (approximately 1000K), thereby reducing thermal and radiation losses from the cathode, a key limiter in thermionic conversion devices. Note that there are two energy conversion steps in the current invention—one photovoltaic, and one thermionic. This double conversion is able to make more efficient use of the available solar spectrum, and thus obtain a higher overall energy conversion efficiency.

Smestad [smestad2004] describes a dual mode solar converter based on a photoelectric energy conversion, and a thermionic energy conversion. The current invention differs from this device in that it uses a photovoltaic energy conversion, rather than a photo-electric energy conversion as one of the photoconversion steps. Compared to the photovoltaic conversion step in the current invention, the photoelectric energy conversion is known to have much lower efficiency.

### SUMMARY

The current invention uses a combination of technologies from dye-sensitized solar cells, and from thermionic generators, to form a unique, efficient, broad spectrum solar radiation to electric power converter. Light passing through the cell first passes through a dye-sensitized matrix of nanoporous semiconductor. Light within the absorption spectrum of the dye is absorbed and converted into electrons which are injected into the conduction band of the semiconductor matrix. Light, which is not absorbed by the dye, passes on to the cathode. The cathode is heated upon absorbing the incoming radiation. At a temperature dependent on the work function of the cathode, the cathode emits electrons thermionically, thereby cooling the cathode. These electrons replenish the electrons in the dye, thus completing the flow of current between cathode and anode. The hot cathode is thermally isolated from portions of the device at ambient temperature, thereby minimizing parasitic thermal loss. The device produces electricity similar to a two junction photovoltaic cell in that the anode voltage is added to the cathode voltage.

### BRIEF DESCRIPTION OF DRAWINGS

FIG. 1 shows a schematic cross sectional diagram of the key elements of the hybrid photovoltaic/thermionic converter.

FIG. 2 shows how ceramic microspheres can be used to mechanically and thermally isolate the high temperature cathode from the anode.

FIG. 3 shows the connectivity of several segments in series to increase the voltage output of the converter.

FIG. 4 shows how metalized ceramic microspheres can be used to provide mechanical separation between cathode and anode, as well as providing electrical connectivity between different devices for series operation.

FIG. 5 shows a cross section of a planar implementation, with devices connected in series, and enclosed in a sealed environment.

FIG. 6 shows a tubular, radial symmetric configuration, with devices connected in series, and enclosed in a sealed environment. It includes cross sections A, B, C and D showing cathode end cap, cross section through center of tube, cross section of surface of tube, and anode end cap.

Note that figures are schematic, intended to show the key system components and their relation to each other, and are not necessarily drawn to scale.

### DETAILED DESCRIPTION

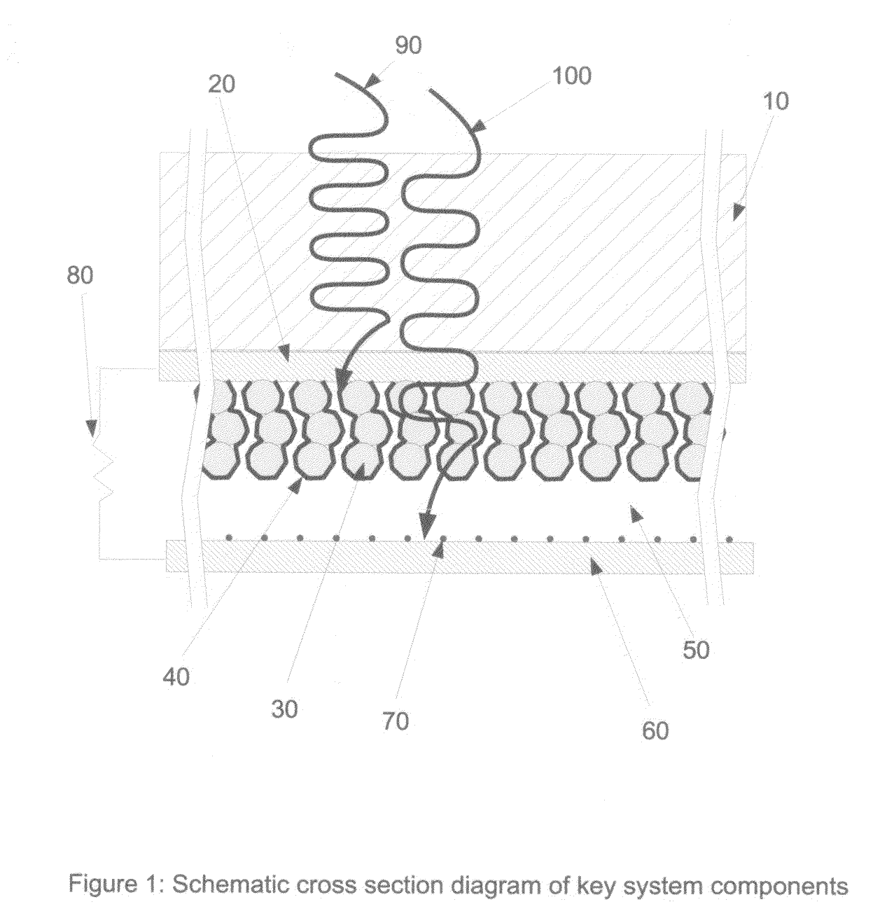

The invention consists of the following parts, illustrated in FIG. 1:

A hot cathode (60) comprising a surface with a high absorption spectrum for light in the solar spectrum, and a low emission coefficient (to reduce re-radiation). Such selective surfaces re currently used, for example, in vacuum based solar fluid heaters. In addition, the cathode is covered with a thermionic emitter material (70) with a low work function.

A cold anode, comprising a transparent electrical conductor coating (20) (possible anode materials include, but are not limited to Indium Tin Oxide and Fluorine Tin Oxide) on a transparent substrate (10). The conductor layer is covered in a mesoporous nanocrystalline semiconductor matrix (30), such as TiO2 in anatase crystalline form. The mesoporous nanocrystalline semiconductor matrix (30) is sensitized, as in a Dye Sensitized Solar Cell (DSSC) [gratzel2003], with a monolayer of organic or inorganic dye chemically adsorbed to the nanocrystalline matrix (40).

A controlled atmosphere (50) is established between the anode and cathode which reduces the transfer of heat from the cathode, but enables the conduction of thermionic electrons from the thermionic emitter (70) on the hot cathode (60) to the dye-sensitized mesoporous nanocrystalline semiconductor matrix (30).

The controlled atmosphere may be: a high quality vacuum; a low pressure gas, such a Cesium, or a Cesium Oxygen mixture, which serves to reduce the work function of the cathode emitter material and/or reduce space-charge effects; a gas mixture maintained by a source which emits a substance into the atmosphere over time to compensate for elements in the gas that are adsorbed to inner surfaces. The controlled atmosphere may be maintained by the addition of a “getter” material (e.g. Cesium) in the enclosed vacuum vessels to collect contaminants which would otherwise reduce the vacuum (e.g. hydrogen infiltration).

The gap between the anode and cathode may be less than 10 micrometers, reducing the potential required to overcome the space charge around the hot cathode.

The thermionic current generated at the cathode must be the same in steady state as the photovoltaic current generated at the anode. The absorption properties of the dye are chosen to optimize the spectrum of radiation absorbed (and therefore the current generated) by the photovoltaic process, and the spectrum of remaining radiation which passes through the dye to the thermionic cathode. Proper choice of dye properties thus allows optimizing the efficiency with which solar radiation is converted by the device into electrical power.

The electrical lead from the hot cathode is chosen to minimize thermal and electrical losses in bridging the interface between the hot cathode and the ambient temperature.

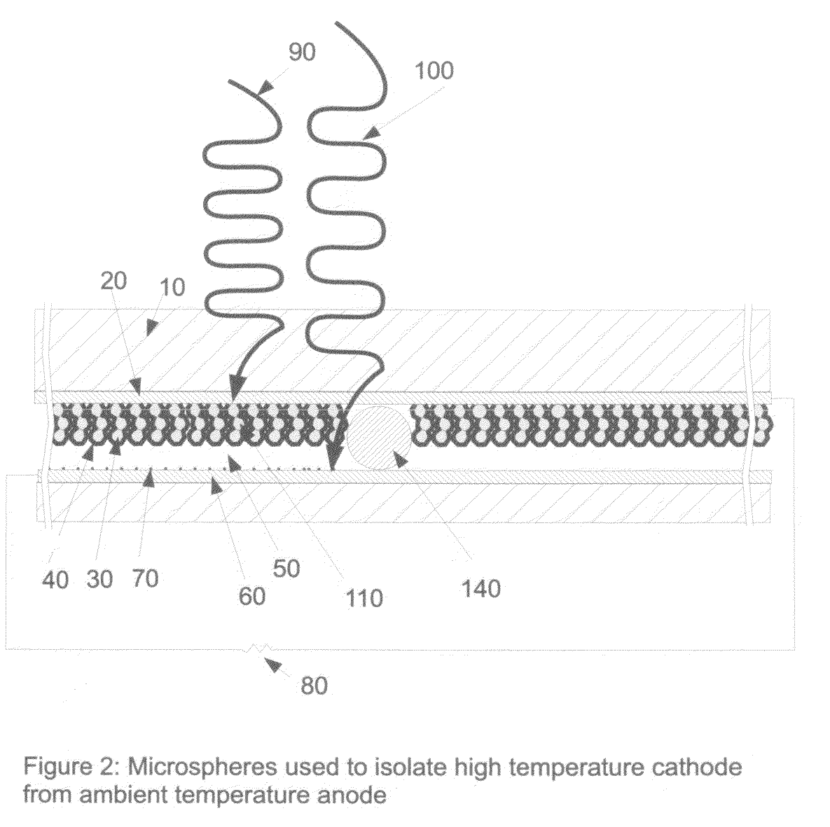

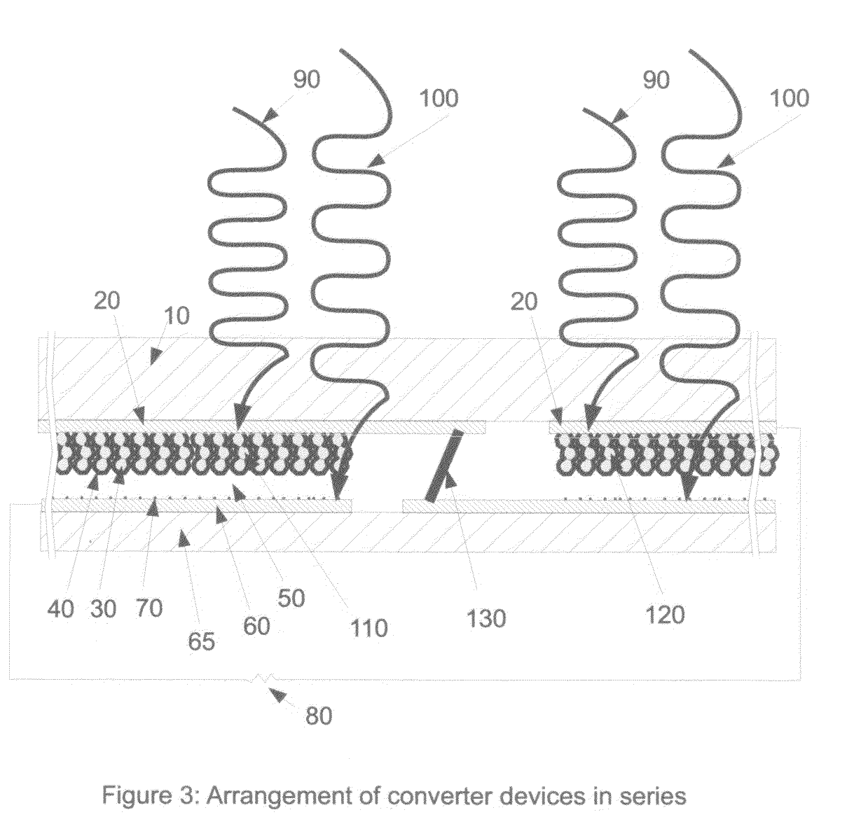

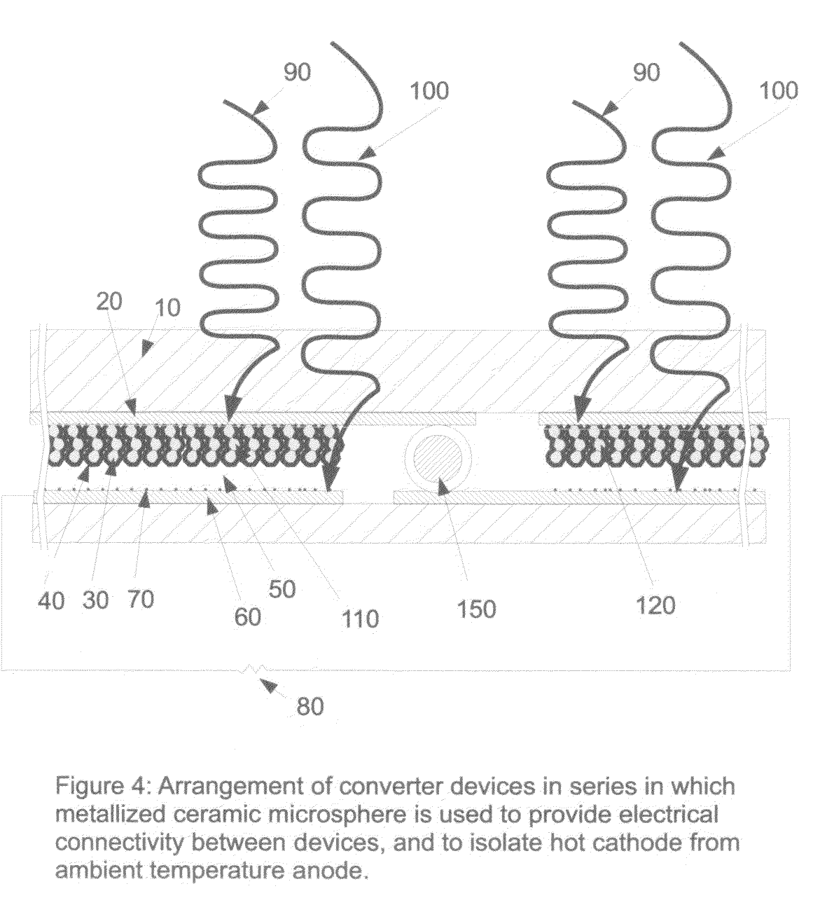

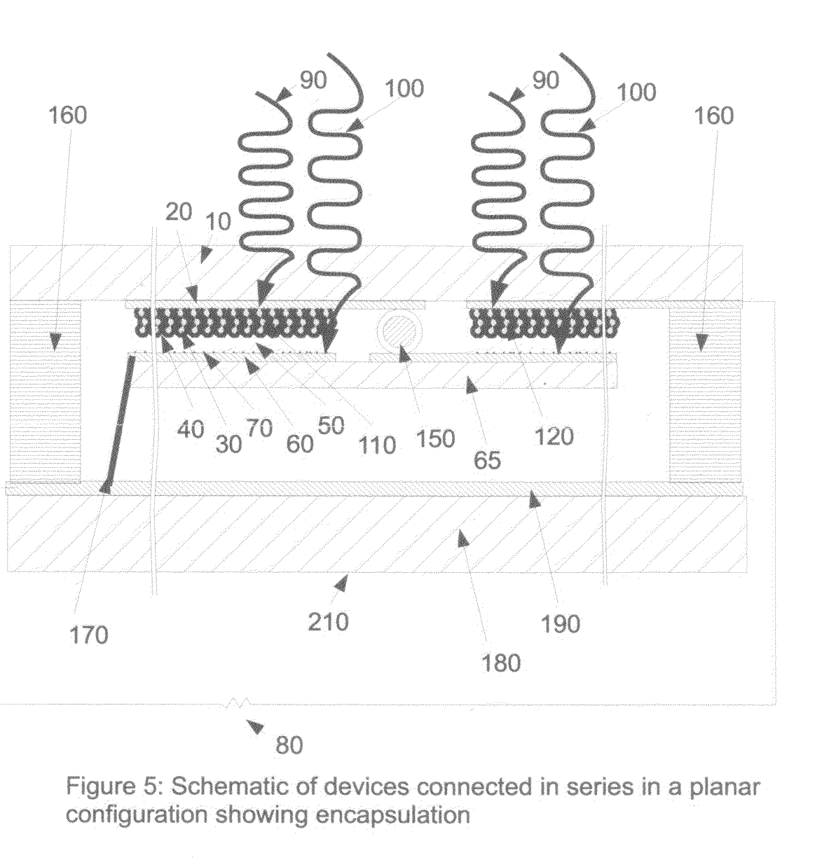

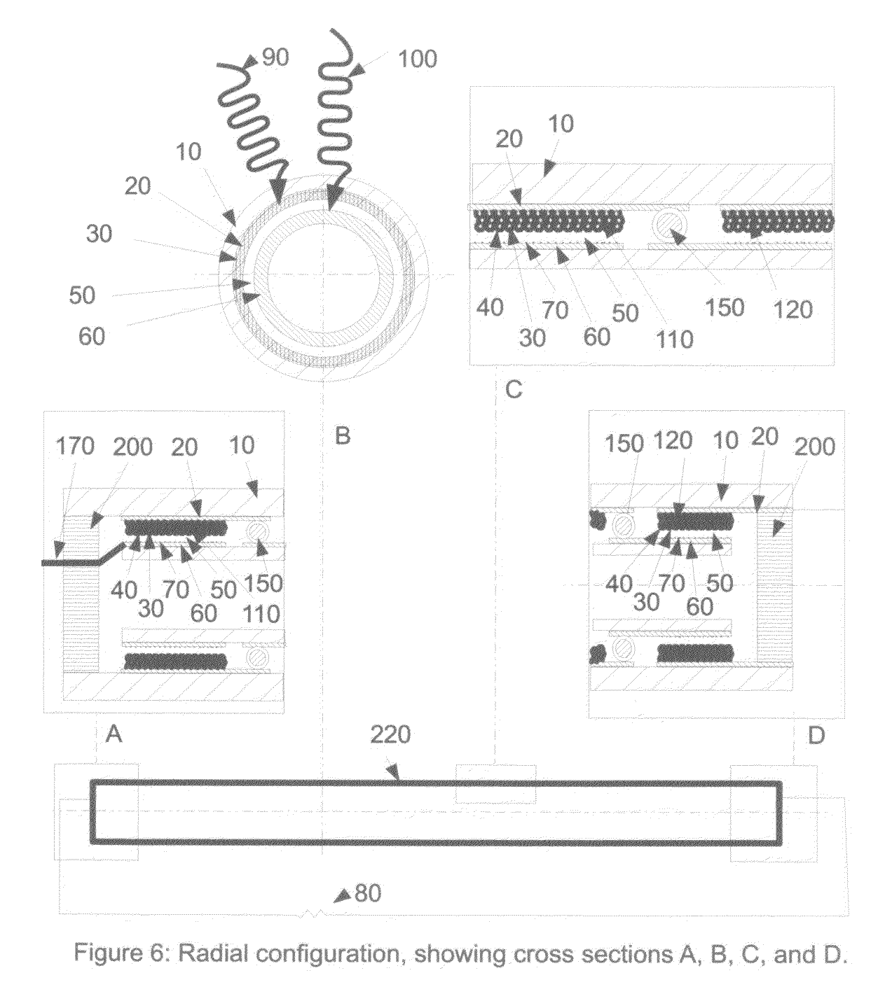

There are several variations on possible practical physical architectures which enable the device operation as described below. These include: a version, shown in FIG. 2, in which the physical separation between the ambient temperature anode and the high temperature cathode is maintained by electrically and thermally insulating ceramic microspheres; a version, shown in FIG. 3, in which a number of cells are created by lithographic “printing” of the anode and cathode surfaces, and in which these devices are connected in series, allowing an overall increase in voltage produced; a version, shown in FIG. 4, in which metallized ceramic microspheres are used both as a mechanical and thermal separator between anode and cathode, as well as the electrical connection between devices connected in series; a version, shown in FIG. 5 in which a planar implementation of the devices is placed in a sealed environment; and a version, shown in FIG. 6 in which a radially symmetric, tubular implementation of series-connected devices are place in a sealed environment.

As shown in FIG. 2, the separation between the anode and the cathode may be maintained by an array of electrically and thermally insulating ceramic microspheres (140) placed between the anode and the cathode. At the appropriate areal densities (e.g. 1-100 microspheres per cm̂2), and with appropriately smooth anode and cathode surfaces, the microspheres create controllable separation between anode and cathode, without incurring unacceptable parasitic heat loss between anode and cathode.

As shown in FIG. 3, two or more (110 and 120) individual cells may be connected in series, allowing higher voltage output at the same current. In one embodiment of series cells, the cells are made by using lithography techniques to “print” anode transparent conductor (20) segments on an optically transparent and electrically insulating substrate (10), and cathode segments (60) on a temperature stable, electrically insulating substrate (65). The cathode of the first cell (110) is connected across the gap by a conductor (130) to the anode of the next cell (120).

As shown in FIG. 4, metalized ceramic microspheres (150) may be used both to separate anode and cathode layers, and to provide electrical connectivity between anode/cathode cells.

As shown in FIG. 5, the device, comprising one or more cells in series may be implemented in a planar configuration (210) in which the transparent substrate (10) and a metallized rear surface (190), with an interstitial perimeter seal (160), which serves to maintain the controlled atmosphere between anode transparent conductor (20) and cathode (60). The metallized rear surface (190) serves to reduce parasitic radiative heat loss from the rear of the high temperature cathode by reflecting radiation back towards cathode (60). Lead conductors from the anode (20) and cathode (170) traverse the perimeter seal (160) and provide the means of extracting electrical power, used to drive a load (80).

As shown in FIG. 6, the device, comprising one or more cells in series may be implemented in a radially symmetric tubular configuration (220). In this case, the transparent substrate (10) and the end caps (200) form a sealed container that preserves a controlled environment within the tubular collector. Cross sections A, B, C and D show various views of the radial arrangement of the transparent substrate (10), the anode transparent conductor(s) (20), the mesoporous nanocrystalline matrix (30), the dye monolayer (40), the controlled atmosphere (50), the cathode (60), the cathode substrate (65), and the thermionic emitter (70). Cross-Section A shows the electrical connection of hot cathode (60) to the cathode conductor lead (170) through the end cap seal (200). Cross section D shows the electrical connection of the anode transparent conductor (20) through the end cap seal (200), to the external load (80). Cross sections A, C, and D also show instances of metallized microspheres (150) which serve to electrically connect anode and cathode of adjoining cells.

Although multiple embodiments of the invention have been described, many variations and modifications will become apparent upon reading the present application.

### DESCRIPTION OF OPERATION

In operation, the device relies on: conversion of solar radiation to heat in the cathode; conversion of heat to electron flow via thermionic emission; conduction of electrons (but insulation of heat) from the cathode to the anode through a controlled atmosphere; absorption of photons from the solar radiation by a dye adsorbed to a mesoporous nanocrystalline semiconductor matrix; rapid injection of the resulting photo-electrons into the conduction band of a nanocrystalline semiconductor matrix; replenishment of the injected electrons from thermionic electrons in the controlled atmosphere between the cathode and the anode; conduction of the photo-injected electrons through the nanocrystalline semiconductor matrix through electron diffusion; to a low-resistance electrical contact, and thence through an external circuit and load to an electrical contact on the cathode. The result of which is that solar radiation is converted to an electrical current and potential via thermionic cooling of the cathode, and via photo-absorption at the anode.

Referring to the system elements in FIG. 1, the device operates as follows:

Concentrated or unconcentrated solar radiation (“light”) (90,100) passes through the transparent substrate (10) and transparent conductor (20) of the anode. Conversion of light energy to electrical potential and current takes place in two places:

(a) a portion of the spectrum (90) is absorbed by the dye sensitized (40) mesoporous nanocrystalline semiconductor matrix (30). Energy from the absorbed photons is converted to electrons which are injected, with high efficiency, into the conduction band of the semiconductor matrix. This leaves the dye molecules positively charged.

(b) light which is not absorbed by the dye (100) passes through the gap between the anode and the cathode and is absorbed by the cathode (60). This light is converted to heat, which raises the temperature of the cathode (60). The cathode (60) has a low thermal emittance, and the controlled atmosphere (50) insulates the cathode (60) from the surrounding ambient temperature components, allowing the cathode temperature to rise well above ambient. When the thermal energy of electrons in a thermionic coating (70) of the cathode (60) exceeds the work function of the emitter, electrons are injected into the gap (50) between the anode and cathode.

Electron flow takes place between the anode and cathode, from thermionic electrons from the cathode (60) towards the positively charged dye molecules (40), where they replace the electrons which were injected into the semiconductor matrix. An external circuit (80) allows the electrons to flow from the anode back to the cathode, thus completing the cycle of photoconversion and electron flow.

Although multiple embodiments of the invention have been described, many variations and modifications will become apparent to those skilled in the art upon reading the present application.

### REFERENCES

[badescu2000] [1] Badescu, Viorel, “ACCURATE UPPER BOUND EFFICIENCY FOR SOLAR THERMAL POWER GENERATION,” International Journal of Sustainable Energy, Volume 20, Issue 3 Jan. 2000, pages 149-160.
[smil2003] [2] Smil, Vaciav, “Energy at the Crossroads: Global Perspectives and Uncertainties,” MIT Press, 2003.
[gratzel2003] [3] Gratzel, Michael, “Review: Dye-sensitized solar cells,” Journal of Photochemistry and Photobiology C: Photochemistry Reviews 4 (2003) 145-153.
[houston1959] [4] Houston. J. M. “Theoretical Efficiency of the Thermionic Energy Converter.” J. Appl. Phys. 30: 481-487 (1959).
[smestad2004] [5] Smestad, Greg, “Conversion of heat and light simultaneously using a vacuum photodiode and the thermionic and photoelectric effects,” Solar Energy Materials & Solar Cells 82 (2004) 227-240.

What is claimed is:

1. An energy conversion device producing a DC voltage and current through a photovoltaic energy conversion process and a thermionic energy conversion process.

2. An energy conversion device as in claim 1 in which the photovoltaic energy conversion process is by rapid injection of photoelectrons from a dye into a mesoporous nanocrystalline semiconductor matrix.

3. An energy conversion device as in claim 1 in which the thermionic energy conversion process is by solar heating of a selective surface which has been coated with a thermionic emitter material and which emits electrons into a vacuum gap.

4. An energy conversion device as in claim 1 in which the photovoltaic energy conversion process is by rapid injection of photo-electrons from a dye into a mesoporous nanocrystalline semiconductor matrix, and in which the thermionic energy conversion process is by solar heating of a selective surface which has been coated with a thermionic emitter material which emits electrons into a gap with a controlled atmosphere. Said gap separating the thermionic emitter from the photovoltaic conductor is sufficiently small, thus allowing electrons emitted from the thermionic energy conversion process to be absorbed by the dye, thus replacing the electrons injected into the semiconductor matrix.

5. An energy conversion device as in claim 4 in which the controlled atmosphere of the gap separating thermionic emitter and photovoltaic layer is a high quality vacuum.

6. An energy conversion device as in claim 4 in which the controlled atmosphere of the gap separating thermionic emitter and photovoltaic layer is a partial atmosphere of ionized, or ionizable gas.

7. An energy conversion device as in claim 4 in which the solar radiation passes through a transparent conductor which serves as the anode electrical contact.

8. An energy conversion device as in claim 4 in which the thermionic coating is applied to a conductor which serves as the cathode electrical contact.

9. An energy conversion device as in claim 7 in which the conductive anode is transparent to shorter wavelength, higher energy radiation, but reflective to longer wavelength, lower energy radiation emitted by the thermionic cathode, thus reducing the rate of parasitic heat loss from the cathode via radiative cooling.

10. An energy conversion device as in claim 1 wherein the photovoltaic conversion process is tuned to absorb energy from the more energetic, higher frequency component of the solar spectrum, and passing the lower energy, lower frequency spectrum of the incoming solar radiation, to the thermionic conversion process.

11. An energy conversion device as in claim 10 where photovoltaic and thermionic energy conversion steps are tuned to extract different parts of the incoming solar spectrum, and optimized to produce maximum power by choosing a optimal band gap for photovoltaic conversion process, and the optimal work function for the thermionic emitter.
